(19) United States
(12) Patent Application Publication
(10) Pub. No.: US 2007/0218709 A1
(43) Pub. Date: Sep. 20, 2007

(54) Computer system and main board equipped with hybrid hypertransport interfaces

(76) Inventor: Shan-Kai Yang, Taipei City (TW)

Correspondence Address: RABIN & Berdo, PC, 1101 14TH STREET, NW, SUITE 500, WASHINGTON, DC, 20005, US

(21) Appl. No.: 11/447,960

(22) Filed: Jun. 7, 2006

(30) Foreign Application Priority Data
Mar. 17, 2006 (TW) 095109345

(51) Int. Cl. H05K 1/00

(52) U.S. Cl. 439/61

(57) ABSTRACT

A computer system comprises a main board equipped with a HT device. The HT interface comprises a first connector and a riser card. The first connector is compatible with HT Device-Under-Test (HT-DUT) specifications and electrically connected onto the main board. The riser card, inserted onto the main board, includes a second connector compatible with HT-DUT specifications and a third connector compatible with HT expansion (HTX) specifications. The first connector and the second connector are electrically connected for data transmission. Therefore, the main board equipped with both the HT-DUT connector and the HTX connector achieves smaller on-board space and fewer on-board connection interfaces.

### BACKGROUND OF THE INVENTION

1. Field of Invention

The invention relates to a HyperTransport™ interface and particularly to a main board equipped with HyperTransport Device-Under-Test (HT-DUT) interface and HyperTransport Expansion (HTX) interface.

2. Related Art

In the manufacturing process of main boards equipped with a HT interface, the HT interface has to be tested in advance to control the production yield. The present test method of the HT interface generally adopts an external test system to do off-board test. Namely a HT compatibility test is performed on a test board through a HT-DUT connector. In actual production of some specific main boards equipped with a HT interface, the original HT-DUT connector is removed and replaced by a HTX connector. However, the aforesaid approach is inconvenient. As the main board during test is installed with a HT-DUT connector, while the main board on the production line is installed with a HTX connector. Hence two different types of main boards have to be designed and fabricated. After the test is finished, the main board installed with the HT-DUT connector is discarded. It is a waste of production manpower and cost. Some main board manufacturers try to provide a main board with two HT interfaces, one has a HTX connector and the other has a HT-DUT connector. Although such an approach can prevent waste of manpower and cost on testing main boards, this type of main board has to include additional electric elements and circuits for installing the HT-DUT connector and the cost increases significantly. Hence at present most main board manufacturers still take the approach, fabricating the main boards with HTX connectors for users and the main boards with HT-DUT connectors for quality control. Meanwhile, for an uncommon interface like HyperTransport, there is always a controversial issue on limited space arrangement for system designers. A HyperTransport connector is not compatible with other common interfaces like PCI-based (Peripheral Component Interconnect) specification (PCI, PCI-E and PCI-X). Generally a system designer chooses common interfaces to meet the majority of customers' requirements.

In the conventional techniques, the HTX and HT-DUT interfaces are located respectively on a single and separated main board. A total solution cannot be provided to save manufacturing manpower and production cost, and to achieve optimum space efficiency at the same time for user demand. Therefore, to provide a main board equipped with desired dual HT interfaces is an urgent need remained to be l-filled.

### SUMMARY OF THE INVENTION

To solve the problems in the prior art, the present invention provides a main board and hybrid HyperTransport (HT) interfaces equipped thereon for a computer system.

In an embodiment of the present invention, the computer system comprises a main board and a HyperTransport (HT) device. The main board is configured with an interface socket. The HT device includes a first connector and a riser card. The first connector is electrically connected to the main board and compatible with HT Device-Under-Test (HT-DUT) specifications. The riser card, electrically connected to the main board, has a second connector and at least one third connector. The second connector is compatible with HT-DUT specifications for electrically connecting with the first connector, while the third connector is compatible with HT expansion (HTX) specifications.

In an embodiment of the present invention, the first connector and the second connector are electrically connected through a flexible printed circuit. The flexible printed circuit may comprise a power supply circuit to provide electricity from the main board, the first connector, the second connector to the riser card. Furthermore, data that follows HT protocols are transmitted between the riser card and the main board through the first connector, the flexible printed circuit and the second connector.

In an embodiment of the present invention, the riser card is supplied with electricity through a power cable and a power supply module. In specific cases, the first and second connectors comprise respectively a Samtec male connector and a Samtec female connector connecting to each other.

In an embodiment of the present invention, the riser card further comprises a pin interface for electrically connecting with the interface socket of the main board. In certain situations, both the pin interface of the riser card and the interface socket of the main board are compatible with PCI (Peripheral Component Interconnect) PCI-E (Peripheral Component Interconnect Express) or PCI-X (Peripheral Component Interconnect Extended) specifications. Moreover, the pin interface of the riser card may comprise at lease one pin to obtain electricity from the interface socket and the main board.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow illustration only, and thus are not limitative of the present invention, and wherein:

FIG. 1 is a schematic side view of an embodiment of the invention;

FIG. 2A is a first perspective view of an embodiment of a riser card of the invention;

FIG. 2B is a second perspective view of an embodiment of a riser card of the invention;

FIG. 3 is a schematic block diagram of an embodiment of a main board architecture of the invention; and

FIG. 4 is a schematic block diagram of an embodiment of data flow and power supply path of a riser card of the invention.

### DETAILED DESCRIPTION OF THE INVENTION

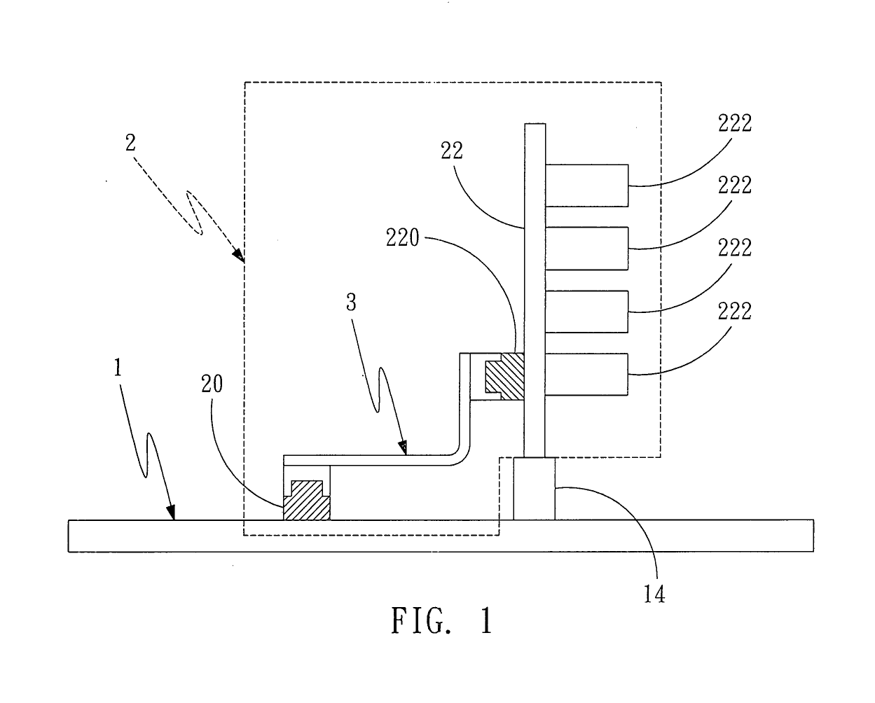

Refer to FIG. 1 for an embodiment of the computer system according to the present invention. In the computer system, a HT device 2 is applied to a main board 1. The main board 1 is provided for electrical connection and data exchange for electronic elements of the computer system. The HT device 2 is an electric interface compatible with HT specifications. The HT specifications adopts communication protocols based on the high speed data transmission interconnect technology for chip-to-chip interconnect specified by the HyperTransport Technology Consortium and related connector technology.

The main board 1 has a plurality of processing chipsets (not shown in the drawings), a bridge chipset (not shown) and a plurality of interface sockets 14. The processing chipsets, performing data processes such as calculation, comparison, selection, determination and the like, includes various types of powerful processors such as a central processing unit (CPU), a micro control unit (MCU), a digital signal processor (DSP), a system-on-chip (SoC), a system-level integration (SLI) chipset and the like. The bridge chipset coordinates frequency or operation of the processing chipsets and the peripheral devices. The sockets aim to couple with various types of interface cards to transmit data or provide required electric power for the interface cards, such as Peripheral Component Interconnect Extended (PCI-X), Peripheral Component Interconnect Express (PCI-E), Accelerated Graphics Port (AGP), Industry Standard Architecture (ISA) and the like.

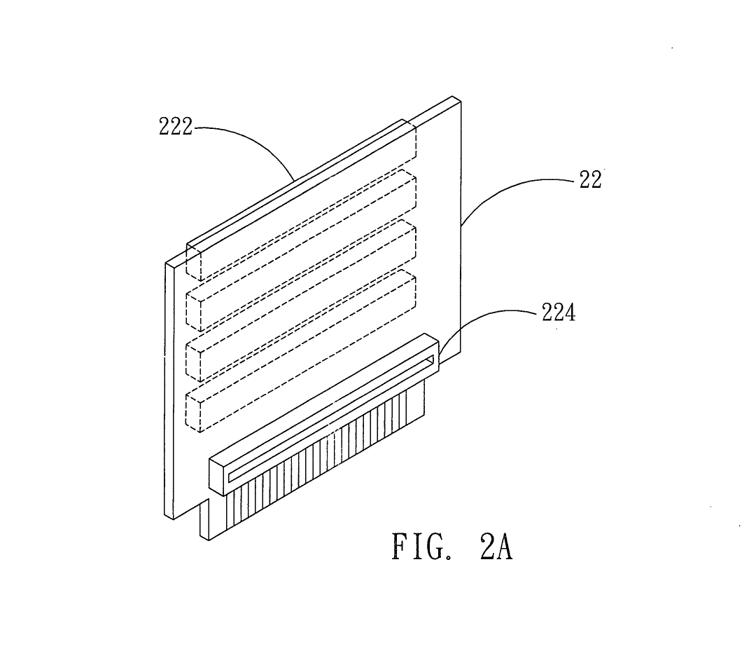

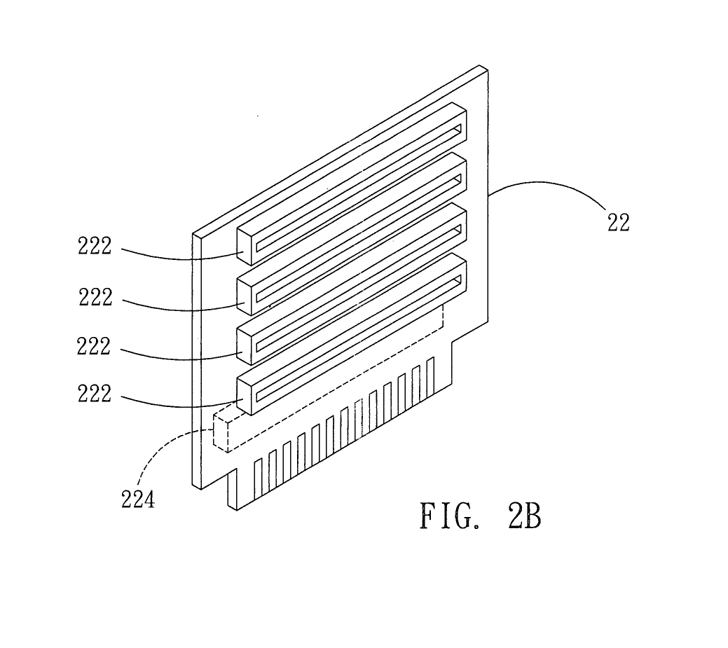

Referring to FIGS. 1, 2A and 2B, the HT device 2 includes a first connector 20 and a riser card 22. The data transmission protocol adopted by the first connector 20 is defined according to the HT interface, while the physical structure of the first connector 20 follows HT-DUT specifications. In practice, the first connector 20 may includes a pair of Samtec male (the portion with oblique lines in FIG. 1) and female (the empty portion in FIG. 1) connectors that are coupled with each other and onto the main board 1 to provide electrical connection. Both the male and the female connectors may be configured on the main board 1 independently to enable the major function, the off-board test. The riser card 22 is a circuit board with a pin interface mounted to the main board 1 through the interface socket 14 to obtain physical support and electricity.

The riser card 22 mentioned above has a second connector 220 and a plurality of third HT connectors 222. The second connector 220 is also a HT transmission interface. A practical embodiment for the second connector 220 includes a pair of Samtec male (the portion with oblique lines in FIG. 1) and female (the empty portion in FIG. 1) connectors that are coupled with each other and onto the riser card 22 to provide electrical connection. Namely, the second connector 220 and the first connector 20 adopt the specifications of HT-DUT interface. For those skilled in the art, the arrangement of either the male or female connector for the HT device 2 should not be a limitation to the invention. The second connector 220 and the first connector 20 form an electric connection there-in-between. The third HT connectors 222 are connectors adopting the specifications of HTX interface.

The second connector 220 and the first connector 20 are electrically connected through a flexible printed circuit (FPC) 3 which has two ends connecting respectively to the first connector 20 and the second connector 220 to perform data transmission according to the HT interface specification.

In specific situations, the FPC 3 may include a power supply circuit to provide electricity directly from the main board 1, the first connector 20, and the second connector 220 to the riser card 22. Another way to supply electricity for the riser card 22 is to directly couple with a power supply module of the whole computer system through a power cable, as utilized in the electricity supply of a hard disk.

The HTX connector provides a chip-to-chip interconnect between two HT interface chipsets, and can be extended to become a connection interface to transmit signals between a subsystem equipped with a HT interface and other interface cards that have a HT interface. The HTX interface can selectively support an 8-digit HT link interface or a 16-digit HT link interface. In addition, the riser card 22 and the interface socket 14 have mating communication interface structures for coupling each other. Take an embodiment as an example, both the pin interface of the riser card 22 and the interface socket 14 are compatible with PCI (Peripheral Component Interconnect), PCI-E (Peripheral Component Interconnect Express) or PCI-X (Peripheral Component Interconnect Extended) specifications. The structural specification of the HTX connector is adaptable to a Rack-mounted server, a Blade server or a Pedestal server. The HT-DUT connector provides a chip-to-chip interconnect between two HT interface chipsets to allow an external test system to perform an off-board test thereby to provide HT compatibility test.

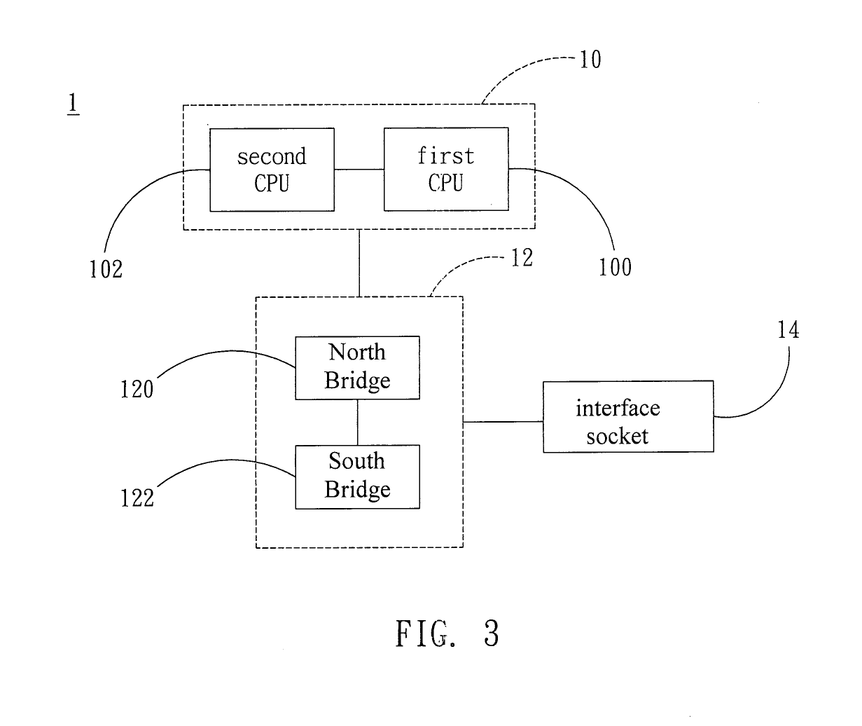

Refer to FIG. 3 for another embodiment of the main board 1. The main board I includes a CPU chipset 10 with a first CPU 100 and a second CPU 102, a bridge chipset 12 with a North Bridge 120 (or called Graphics and Memory Controller Hub—MCH) and a South Bridge 122 (or called Input and Output Controller Hub—ICH), and an interface socket 14. Another architecture of the main board 1 may include multiple processors, each integrated with at least one memory controller for dedicated system memories respectively. The processors will then connect each other and the South Bridge.

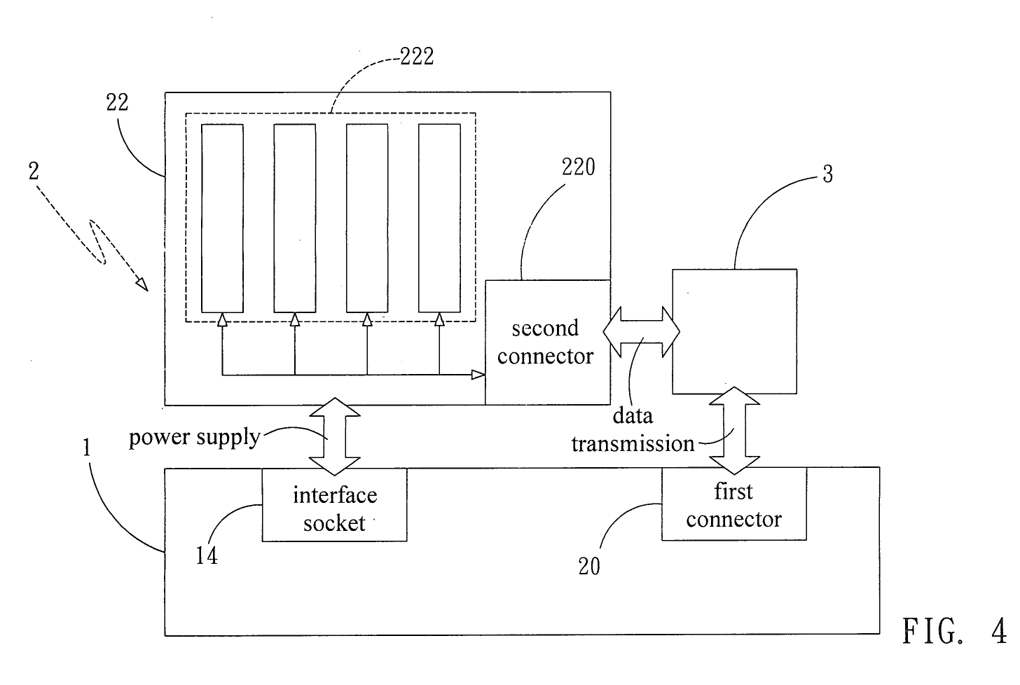

Refer to FIG. 4 for an embodiment of data transmission and power supply of the riser card according to the invention. When the system is operating, data that follows the HT protocol can be directly transmitted to the riser card 22 through the first connector 20, FPC 3 and second connector 220. Through the second connector 220 and the third HT connectors 222 of the riser card 22, HT interconnection functions can be accomplished, thereby enable expansion cards that follows HTX specifications to insert to the third HT connectors for electrical connection. The electricity required by the riser card 22 is supplied through the interface socket 14 of the main board 1. To realize the embodiment on a PCI/PC1-X/PCI-E interface socket, one or more pins of the pin interface on the riser card will be dedicatedly defined according to the power pins of the PCI/PCI-X/PCI-E interface socket to obtain electricity from the interface socket and the main board. By configuring a Samtec male or female connector on the main board 1, both HT-DUT and HTX interface can be provided through the HT device 2 of the invention.

In addition, through the coupling of the riser card 22 and the interface socket 14, the riser card 22 can be mounted onto the main board 1 to form a structure in a smaller on-board space and fewer on-board connection interfaces (namely a single interface socket 14). Thus it can achieve optimal utilization in a smaller space. Therefore the mechanical specification of the invention is adaptable to a Rack-mounted server or a Pedestal server.

In short, the invention provides a main board equipped with both HT-DUT connector and HTX connector by coupling the riser card with the socket. Therefore the HT-DUT connector of the riser card can be used to perform HT compatibility test to achieve an improved production yield of the HT-enabled main board. And meanwhile, provide HTX expansion functions by inserting HTX cards into the HTX connectors (third HT connectors) configured on the riser card.

Moreover, by coupling the riser card with the socket, the computer system of the invention can be formed in a minimum on-board space and minimum on-board connection interface. It can meet the requirements of HT-DUT and HTX interfaces. Compared with the conventional techniques that have to produce two types of main boards, or one main board with a HT-DUT interface and a HTX interface, the invention can save production manpower and cost in the main board manufacturing process.

Thus the invention not only can provide HT-DUT interface and HTX interface, also provides a structure that requires a minimum on-board space and a minimum on-board connection interface to achieve optimal utilization of production manpower, cost and structural main board space.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A HyperTransport (HT) device for a main board, comprising:
a first connector electrically connected to the main board, compatible with HT Device-Under-Test (HT-DUT) specifications; and
a riser card electrically connected to the main board, having a second connector and at least one third connector, the second connector being compatible with HT-DUT specifications for electrically connecting the first connector, and the third connector being compatible with HT expansion (HTX) specifications.

2. The HT device of claim 1, wherein the first connector and the second connector are electrically connected through a flexible printed circuit.

3. The HT device of claim 2, wherein the flexible printed circuit comprises a power supply circuit to provide electricity from the main board, the first connector, the second connector to the riser card.

4. The HT device of claim 2, wherein data with HT protocols are transmitted between the riser card and the main board through the first connector, the flexible printed circuit and the second connector.

5. The HT device of claim 1, wherein the riser card is supplied with electricity through a power cable and a power supply module.

6. The HT device of claim 1, wherein the main board further comprises an interface socket and the riser card further comprises a pin interface for electrically connecting with the interface socket.

7. The HT device of claim 6, wherein both the pin interface of the riser card and the interface socket of the main board are compatible with PCI (Peripheral Component Interconnect), PCI-E (Peripheral Component Interconnect Express) or PCI-X (Peripheral Component Interconnect Extended) specifications.

8. The HT device of claim 6, wherein the pin interface of the riser card comprises at lease one pin to obtain electricity from the interface socket and the main board.

9. The HT device of claim 1, wherein the first connector comprises a Samtec male connector and a Samtec female connector connecting to each other.

10. The HT device of claim 1, wherein the second connector comprises a Samtec male connector and a Samtec female connector connecting to each other.

11. A computer system comprising:
a main board configured with an interface socket; and
a HyperTransport (HT) device comprising:
a first connector electrically connected to the main board, compatible with HT Device-Under-Test (HT-DUT) specifications; and
a riser card electrically connected to the main board, having a second connector and at least one third connector, the second connector being compatible with HT-DUT specifications for electrically connecting with the first connector, and the third connector being compatible with HT expansion (HTX) specifications.

12. The computer system of claim 11, wherein the first connector and the second connector are electrically connected through a flexible printed circuit.

13. The computer system of claim 12, wherein the flexible printed circuit comprises a power supply circuit to provide electricity from the main board, the first connector, the second connector to the riser card.

14. The computer system of claim 12, wherein data with HT protocols are transmitted between the riser card and the main board through the first connector, the flexible printed circuit and the second connector.

15. The computer system of claim 11, wherein the riser card is supplied with electricity through a power cable and a power supply module.

16. The computer system of claim 11, wherein the riser card further comprises a pin interface for electrically connecting with the interface socket of the main board.

17. The computer system of claim 16, wherein both the pin interface of the riser card and the interface socket of the main board are compatible with PCI (Peripheral Component Interconnect), PCI-E (Peripheral Component Interconnect Express) or PCI-X (Peripheral Component Interconnect Extended) specifications.

18. The computer system of claim 16, wherein the pin interface of the riser card comprises at lease one pin to obtain electricity from the interface socket and the main board.

19. The computer system of claim 11, wherein the first connector comprises a Samtec male connector and a Samtec female connector connecting to each other.

20. The computer system of claim 11, wherein the second connector comprises a Samtec male connector and a Samtec female connector connecting to each other.
